(19) United States
(12) Patent Application Publication
(10) Pub. No.: US 2025/0279018 A1
(43) Pub. Date: Sep. 4, 2025

(54) FLEXIBLE VOLTAGE GATE HIGH (VGH) SETTING AND VOLTAGE CALIBRATION

(71) Applicant: Google LLC, Mountain View, CA (US)

(72) Inventors: Hsin-Yu CHEN, Taoyuan (TW); Jaewon CHOI, Hwaseong-si (KR); Chang Ju KANG, San Jose, CA (US)

(73) Assignee: Google LLC, Mountain View, CA (US)

(21) Appl. No.: 18/592,757

(22) Filed: Mar. 1, 2024

(51) Int. Cl. G09G 3/00; G01R 19/165; H04M 1/24

(52) U.S. Cl. CPC G09G 3/006; G01R 19/16576; H04M 1/24; G09G 2320/02; G09G 2330/021; G09G 2330/12

(57) ABSTRACT

Some implementations relate to configuring a high level gate voltage (VGH) of a display, such as a computing device including the display, a computer-implemented method to control the display, and a cellular phone including the display. The display is configured by measuring an abnormality voltage threshold, determining a risk level based on the abnormality voltage threshold, and setting the VGH of the display based on the risk level. There may also be a mechanism to periodically check if the risk level for the display has changed (by updating the measured abnormality voltage threshold). If the risk level changes, the VGH is changed accordingly. For example, if a risk level is a low risk level, the display may be set to a low default VGH level, while if the risk level is not a low risk level, the display may be set to a high enhanced VGH level.

### TECHNICAL FIELD

Implementations relate generally to voltage gate high (VGH) setting and voltage calibration, and in particular to flexible VGH setting and voltage calibration.

### BACKGROUND

Portable devices such as mobile phones, tablets, etc. may encounter a green flash issue on their displays. This issue is traced to the critical voltage gate high voltage (VGH voltage) that controls the display on/off functions. Display panel performance is fine-tuned based on a fixed VGH value/setting. For example, a given device model might have a certain baseline voltage setting. Deviations from this specified value leads to display irregularities. To mitigate these problems, a safety threshold for the gate high voltage is established by increasing the VGH setting (for example, from a baseline voltage or voltage range to a higher voltage or voltage range) to provide more space for avoiding irregularities (e.g., green flash) during use. However, this comes at the cost of higher power consumption by the device.

It is possible to increase the value of VGH to provide a bigger driving margin. However, this increased voltage increases power consumption. It is sometimes appropriate to increase VGH (to avoid the flashes), but only when necessary to conserve power.

Some implementations were conceived in light of the above.

The background description provided herein is for the purpose of presenting the context of the disclosure. Work of the presently named inventors, to the extent it is described in this background section, as well as aspects of the description that may not otherwise qualify as prior art at the time of filing, are neither expressly nor impliedly admitted as prior art against the prior disclosure.

### SUMMARY

Implementations of this application relate to flexible VGH setting and voltage calibration. For example, the disclosed displays and the devices with which they are associated may have a VGH setting based on characteristics of the display's operation and how these change over time.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by a data processing apparatus, cause the apparatus to perform the actions.

According to one aspect, there is provided a computing device comprising a processor coupled to a display, wherein a high level gate voltage (VGH) of the display is configured by: measuring an abnormality voltage threshold for the display; determining a risk level for the display based on the abnormality voltage threshold; and setting the VGH of the display based on the risk level.

Various implementations of the computing device are described herein.

In some implementations, setting the VGH comprises setting the VGH to a predetermined low value when the risk level is a low risk level and setting the VGH to a predetermined high value when the risk level is not the low risk level.

In some implementations, setting the VGH of the display is performed in a factory before the computing device is shipped.

In some implementations, the VGH is adjusted after the display has been in use, by: determining whether the risk level for the display has changed; and in response to determining that the risk level for the display has changed, adjusting the VGH of the display.

In some implementations, determining that the risk level for the display has changed comprises: determining if the abnormality voltage threshold for the display has increased based on one or more of: measuring, using a power management integrated circuit (PMIC) of the computing device, an increase exceeding a threshold increase in supplied current supplied by an electronic low voltage supply source (ELVSS) to the display in response to a predetermined decrease in VGH; detecting the abnormality voltage threshold using an abnormality voltage detection component of the device, wherein the abnormality voltage detection component detects abnormal behavior by the display; and detecting the abnormality voltage threshold based on detecting an increase exceeding a threshold increase in supplied current measured using a System-on-a-Chip (SoC) of the computing device in response to a predetermined decrease in VGH, and wherein adjusting the VGH of the display comprises increasing the VGH.

In some implementations, determining that the risk level for the display has changed comprises determining if the abnormality voltage threshold for the display has decreased, and wherein adjusting the VGH of the display comprises decreasing the VGH.

In some implementations, determining whether the measuring the abnormality voltage threshold and the determining the risk level for the display has changed are performed at multiple occasions during a lifetime of the computing device and the setting the VGH is performed based on the measuring and the determining.

In some implementations, the display includes a thin-film transistor (TFT) panel.

According to another aspect, there is provided a computer-implemented method to control a high level gate voltage (VGH) of a display, comprising: measuring an abnormality voltage threshold for the display; determining a risk level for the display based on the abnormality voltage threshold; and setting the VGH of the display based on the risk level.

Various implementations of the computer-implemented method are described herein.

In some implementations, setting the VGH comprises setting the VGH to a predetermined low value when the risk level is a low risk level and setting the VGH to a predetermined high value when the risk level is not the low risk level.

In some implementations, setting the VGH of the display is performed in a factory before the computing device is shipped.

In some implementations, the VGH is adjusted after the display has been in use, by: determining whether the risk level for the display has changed; and in response to determining that the risk level for the display has changed, adjusting the VGH of the display.

In some implementations, determining that the risk level for the display has changed comprises: determining if the abnormality voltage threshold for the display has increased based on one or more of: measuring, using a power management integrated circuit (PMIC) of the computing device, an increase exceeding a threshold increase in supplied current supplied by an electronic low voltage supply source (ELVSS) to the display in response to a predetermined decrease in VGH; detecting the abnormality voltage threshold using an abnormality voltage detection component of the device, wherein the abnormality voltage detection component detects abnormal behavior by the display; and detecting the abnormality voltage threshold based on detecting an increase exceeding a threshold increase in supplied current measured using a System-on-a-Chip (SoC) of the computing device in response to a predetermined decrease in VGH, and wherein adjusting the VGH of the display comprises increasing the VGH.

In some implementations, determining that the risk level for the display has changed comprises determining if the abnormality voltage threshold for the display has decreased, and wherein adjusting the VGH of the display comprises decreasing the VGH.

In some implementations, determining whether the measuring the abnormality voltage threshold and the determining the risk level for the display has changed are performed at multiple occasions during a lifetime of the computing device and the setting the VGH is performed based on the measuring and the determining.

In some implementations, the display includes a thin-film transistor (TFT) panel.

According to another aspect, there is provided a cellular phone including a computing device comprising a processor coupled to a display, wherein a high level gate voltage (VGH) of the display is configured by: measuring an abnormality voltage threshold for the display; determining a risk level for the display based on the abnormality voltage threshold; and setting the VGH of the display based on the risk level.

Various implementations of the cellular phone are described herein.

In some implementations setting the VGH of the display is performed in a factory before the cellular phone is shipped.

In some implementations, the VGH is adjusted after the display has been in use, by: determining whether the risk level for the display has changed; and in response to determining that the risk level has changed, adjusting the VGH of the display.

In some implementations, determining that the risk level for the display has changed comprises: determining if the abnormality voltage threshold for the display has increased based on one or more of: measuring, using a power management integrated circuit (PMIC) of the computing device, an increase exceeding a threshold increase in supplied current supplied by an electronic low voltage supply source (ELVSS) to the display in response to a predetermined decrease in VGH; detecting the abnormality voltage threshold using an abnormality voltage detection component of the device, wherein the abnormality voltage detection component detects abnormal behavior by the display; and detecting the abnormality voltage threshold based on detecting an increase exceeding a threshold increase in supplied current measured using a System-on-a-Chip (SoC) of the computing device in response to a predetermined decrease in VGH, and wherein adjusting the VGH of the display comprises increasing the VGH.

According to yet another aspect, portions, features, and implementation details of the systems, methods, and non-transitory computer-readable media may be combined to form additional aspects, including some aspects which omit and/or modify some or portions of individual components or features, include additional components or features, and/or other modifications, and all such modifications are within the scope of this disclosure.

### BRIEF DESCRIPTION OF DRAWINGS

FIG. 1 is a flowchart illustrating an example method to configure a high level gate voltage (VGH) of a display, in accordance with some implementations.

FIG. 2 is a flowchart illustrating an example method to reconfigure a high level gate voltage (VGH) of a display, in accordance with some implementations.

FIG. 3 is a flowchart illustrating an example method to identify an abnormality voltage threshold of a display, in accordance with some implementations.

FIG. 4 is a block diagram illustrating a cellular phone with a display having a reconfigurable high level gate voltage (VGH), in accordance with some implementations.

FIG. 5 illustrates groupings of displays with various risk characteristics.

FIG. 6 illustrates an example of a process flow, in accordance with some implementations.

FIG. 7 is a block diagram illustrating an example computing device, in accordance with some implementations.

### DETAILED DESCRIPTION

Described features provide a way to avoid green flashes and other artifacts on a display, e.g., a TFT display used in a smartphone, by controlling voltage level supplied to the display based on display characterization. A high level gate voltage (VGH) is a voltage supplied to a display such as a thin-film transistor (TFT) display. A display panel maker tunes a display based on a fixed VGH value. If the actual VGH of a particular display panel is significantly lower than the tuned value, a display may exhibit abnormalities, such as a green flash.

A threshold voltage value at which a display begins to exhibit such abnormalities may be referred to as VGH T0. A driving margin may be provided between the VGH of the display and the VGH T0 to avoid abnormalities. However, sometimes over time, as the display is used, usage conditions may cause VGH T0 increase over time, leading to a display abnormality.

To avoid green flashes while enabling continued use of the display at low power consumption, described implementations provide for multiple, adaptive VGH settings based on display characterization of individual display panels. Implementations may include performing a risk assessment for a set of display units, such as by dividing display units into a “Low Risk” group and a “High Risk” group. For the “Low Risk” group, a lower VGH voltage may be set as an initial, default setting in the device in which the display unit is placed. However, for display units with a “Potential Risk” and/or “High Risk,” a higher VGH voltage may be applied as an enhanced setting. Two, three, or more groupings may be used, with correspondingly different VGH voltage settings.

Over time, as the display is used, the VGH T0 may increase, such as due to cumulative electrostatic discharge (ESD) stresses. The device is configured to periodically perform checks to determine if there are changes to the VGH T0 of the display. For example, the device may measure an electric current from an electronic low voltage supply source (ELVSS) using a Power Management Integrated Circuit (PMIC) or a system on a chip (SoC). If measurement of VGH T0 reveals a change, adjustments may be made to the VGH. Electric current information changes based on VGH, such that an decrease in VGH increases the electric current.

There may be a change caused in such electric current in response to each set voltage decrease in VGH. Initially, the electric current may stay fairly stable and the change in electric current caused by a VGH change is minimal. However, at some VGH value, the change in electric current after a decrease in VGH may exceed a threshold amount. This VGH value indicates VGH T0 because lowering VGH further beneath VGH T0 may cause a surge in electric current and associated display abnormalities.

For example, it may be observed that specified decreases in VGH initially cause only minimal changes to the electric current. Then, a specified decrease in VGH by a set voltage amount increases the electric current by more than a threshold amount (e.g., measured in milliamperes). Such an observation indicates VGH T0 is the lowest value of VGH before decreasing VGH further causes a surge in electric current. Such a surge in electric current may signal the presence of display abnormalities. Alternatively, a specialized component of the device may track changes in VGH T0 more directly, such as by identifying unusual display behavior.

When VGH T0 of a display unit in a device increases over the “Low Risk” range, the higher VGH voltage is applied in the enhanced setting. If the VGH T0 goes back into the “Low Risk” range, a lower VGH voltage is utilized as a default setting. Various implementations described herein perform dynamic and flexible voltage tuning in a mobile device to provide flexible voltage (VGH) settings and voltage calibration for the display unit.

In some implementations, a display-driving application device supports multiple voltage gate high (VGH) settings and performs VGH settings adjustment autonomously, offering dynamic flexibility during initial calibration in a factory and/or during field use of a device, instead of relying on a fixed voltage (VGH) setting. The VGH setting for a device is set in a manner such that the device can continue to operate at low power and gain more margin (since VGH is much more stable in the device). This can include, for example, selecting a lower VGH voltage as the default setting (e.g., the device saves power) for a large majority of units that operate in the low risk group (e.g., VGH T0 is in a low range) while selecting a higher VGH voltage value as the default setting for devices in other risk groups.

However, a higher VGH voltage is set as an enhanced setting (e.g., the device gains more protection area for a small minority of units) if the device is operated in the potential risk (e.g., VGH T0 is in a medium range above that of the low risk group) or the high risk group (e.g., VGH T0 is greater than a high threshold). Such a setting may occur at the factory such that some specific devices have different initial settings than other specific devices, based on their initial display properties. However, in the field, there are periodic checks to confirm if any display properties have changed. Various devices can then take action to change settings accordingly.

After such periodic checks, upon detecting an increase in the VGH T0 over the low risk range, a higher VGH voltage is applied as the enhanced setting. Upon detection of a decrease in the VGH T0 back to the low risk range, a lower VGH voltage is applied as the default setting.

Thus, some TFT displays (e.g., 15% of the displays) have green flashes (or other display abnormalities) at certain voltages. Selecting a single setting for all displays to avoid the green flashes increases power consumption of the devices. Therefore, devices are grouped into risk categories and appropriate device-specific voltages are chosen when calibrating in the factory. As a given device is used, the risk group may change due to operational conditions. In an updating step, these changes are measured and the voltages are adjusted accordingly. The updating step is repeated periodically.

The implementations provide a number of technical benefits. As noted, if the VGH of a display unit is too low, greenish flashes or other visual artifacts may occur. However, if the VGH is set to a high value to avoid the likelihood of such artifacts, an unnecessary amount of power may be consumed during the time the display is on. Implementations, on a per device basis, flexibly set VGH, such that over the entire fleet of devices, green flashes are prevented and power consumption is lowered. Hence, various implementations provide good display performance, efficient power usage, and automatic adjustments to easily achieve these results.

Thus, in some implementations, when setting a VGH for a display, various techniques provide ways to ascertain a threshold for which VGH values are likely to lead to inappropriate display behavior. Based on this information, an operating VGH may be changed automatically by a display or by a device containing the display, such as a cell phone. Such operation saves energy when it is possible to do so, but avoids screen problems by increasing VGH when necessary. Further, some implementations check for problematic VGH periodically, and automatically adjust VGH accordingly.

In this disclosure, a number of particular values have been discussed as illustrative examples. For example, the disclosure refers to general voltage ranges and general current values as corresponding to particular risk groups and particular voltage settings for specific implementations. These particular voltage and current values each correspond to a particular illustrative implementation. However, it may be recognized that other ranges may be relevant/applicable in other implementations. The general concepts (such as relative values or ranges, or benefits and advantages) may be preserved in a variety of other implementations. For example, the concepts may be applied to a range of display technologies, where the displays are associated with a variety of devices. In some implementations, the device may be a cellular phone, but the operational parameters would apply in a number of different contexts, such as a tablet, a laptop computer, a wearable device, other portable devices, and so on.

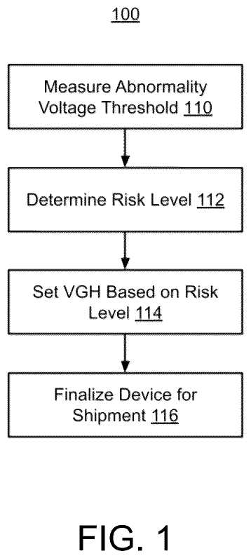

### FIG. 1—Configuring a High Level Gate Voltage (VGH) of a Display

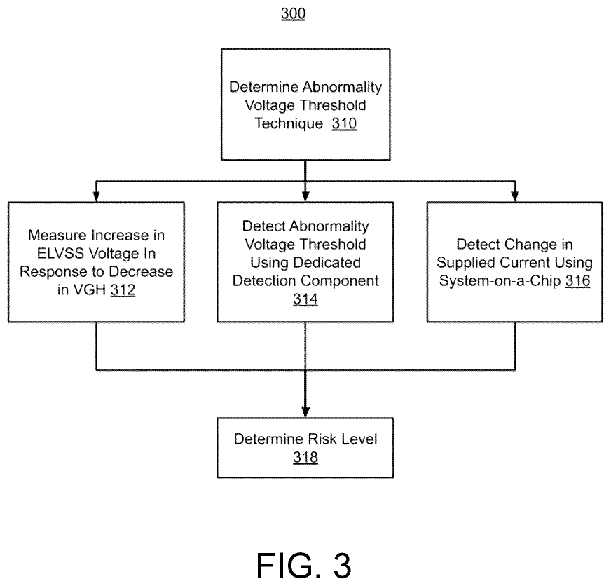

FIG. 1 is a flowchart illustrating a method 100 for configuring a high level gate voltage (VGH) of a display, in accordance with some implementations. Method 100 begins at block 110. At block 110, an abnormality voltage threshold (also referred to as VGH T0) for a display may be measured. In some implementations, the measurement includes measuring an increase in EL VSS voltage in response to a decrease in VGH using a power management integrated circuit (PMIC). In some implementations, the measurement includes detecting an abnormality voltage threshold using a dedicated detection component. In some implementations, the measurement includes detecting a change in supplied current using a system-on-a-chip (SoC). These techniques are discussed further with respect to FIG. 3. Block 110 may be followed by block 112.

At block 112, a risk level for the display may be determined. In some implementations, the risk level for the display may be based on which range of voltages the abnormality voltage threshold (VGH T0) falls into. For example, if VGH is greater than a threshold value, the display may be a high risk display. If VGH T0 is within a moderate range, the display may be a potential risk display. If VGH T0 is in a low range, the display may be a low risk display. For such an example, these three ranges are non-overlapping and a display falls into only one category. In various implementations, two, three, or more ranges may be used. There may be various example ranges, and in other implementations (such as different displays/devices) these ranges may differ. If Block 112 may be followed by block 114.

At block 114, the VGH of a display may be set based on the risk level. For example, the VGH may be set to a lower default setting of a certain base voltage or a higher enhanced setting of an increased voltage beyond the base voltage. If the risk level is the low risk level, the VGH may be kept at a default, low value setting. If the risk level is the potential risk level or the high risk level, the VGH may be set to the enhanced (higher value) setting. Block 114 may optionally be followed by block 116.

While block 112 and block 114 are recited as determining a risk level of low risk, potential risk, or high risk and configuring the VGH to a specific default or enhanced setting, other implementations may operate in related ways. For example, there may be only low risk and high risk groups, or there may be more than three groups, or a numerical risk score. Accordingly, there may be more than two settings, or the risk score may be used to select a VGH setting.

At block 116, a device may be finalized for shipment. For example, the display of the device may be preset to a VGH that corresponds to an initial risk level and thus ready for shipment and initial usage with assurance that green flash or other display abnormalities are not seen during use.

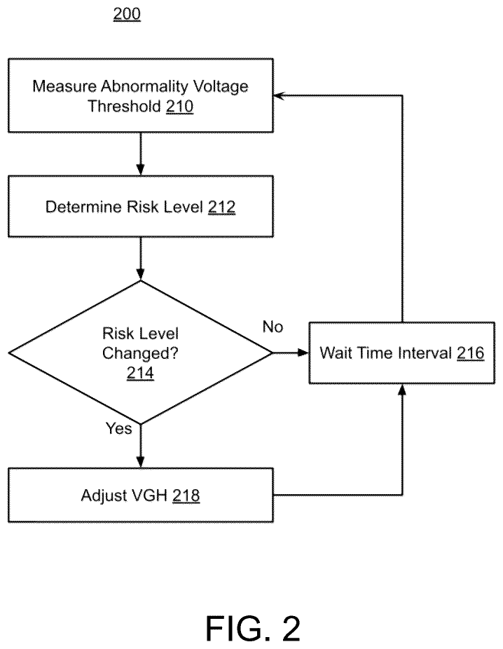

### FIG. 2—Reconfiguring a High Level Gate Voltage (VGH) of a Display

FIG. 2 is a flowchart illustrating a method 200 to reconfigure a high level gate voltage (VGH) of a display, in accordance with some implementations. Method 200 begins at block 210.

At block 210, an abnormality voltage threshold (VGH T0) for the display is measured. For example, this measurement updates the VGH T0 value. Such measurement may be performed periodically to see if the operation of the display has changed. For example, the measurement may be performed at certain time intervals. The measurement may also be performed in response to certain events, such as a power-on event, detected damage to the display (such as an electrostatic discharge (ESD) event) or a received command to check display status. The threshold may be measured as in block 110, using the techniques detailed in FIG. 3. Block 210 may be followed by block 212.

At block 212, a risk level for the display is determined. For example, this determination updates the risk level. The risk level is determined as in block 112. That is, it is determined which range of voltage values VGH T0 falls into. For example, the risk level may be a low risk level, a potential risk level, or a high risk level. Block 212 may be followed by block 214.

At block 214, it is determined if the risk level for the display has changed. A change in VGH T0 is not always considered to be a change in risk level, in that risk levels cover a range of VGH T0 values. If the risk level is represented by a score, there may be a minimum change of score before a risk level is considered to be changed. If so, block 214 is followed by block 218. If not, block 214 is followed by block 216.

At block 216, the device waits a time interval. In some implementations, the time interval may be a day, a week, a month or so on. However, these are merely examples and the measurement of abnormality voltage threshold for the device may be performed at any suitable interval. Block 216 may be followed by block 210, so that the device can check again for significant changes to VGH T0.

At block 218, the VGH is adjusted based on the changed risk level. In some implementations, a default setting (such as a set lower voltage) may be changed to an enhanced setting (such as a set higher voltage) if a low risk display is reclassified as a potential risk display or a high risk display. Similarly, in some implementations, an enhanced setting (such as a set higher voltage) may be changed to a default setting (such as a set lower voltage) if a high risk display or potential risk display is reclassified as a low risk display. Block 218 may be followed by block 216.

### FIG. 3—Identifying an Abnormality Voltage Threshold of a Display

FIG. 3 is a flowchart illustrating a method 300 for identifying an abnormality voltage threshold of a display, in accordance with some implementations. Method 300 begins at block 310.

At block 310, one or more techniques to determine the abnormality voltage threshold (VGH T0) are selected. Block 310 may be followed by one or more of block 312, block 314, or block 316, depending on the determination. Block 312, block 314, and block 316 each represent an approach for finding VGH T0. For example, in some implementations, one of blocks 312, 314, and 316 may be executed, and other blocks skipped. For example, in some implementations, two of blocks 312, 314, and 316 may be executed, and the remaining block skipped. In some implementations, all of blocks 312, 314, and 316 may be executed, and other blocks skipped. When two or more of blocks 312, 314, and 316 are executed, in some implementations, risk level determination may be based on any of the blocks determining the threshold. Based on current phone designs, it is possible to use a power management integrated circuit (PMIC) to detect the abnormality by measuring an electronic low voltage supply source (ELVSS) voltage. In some implementations, various components such as a PMIC or a System-on-a-Chip (SoC) may have a pin to detect a display screen voltage or data current, indicating display behavior. These techniques may be suitable for initial configuration in a factory to tune an initial setting for a display.

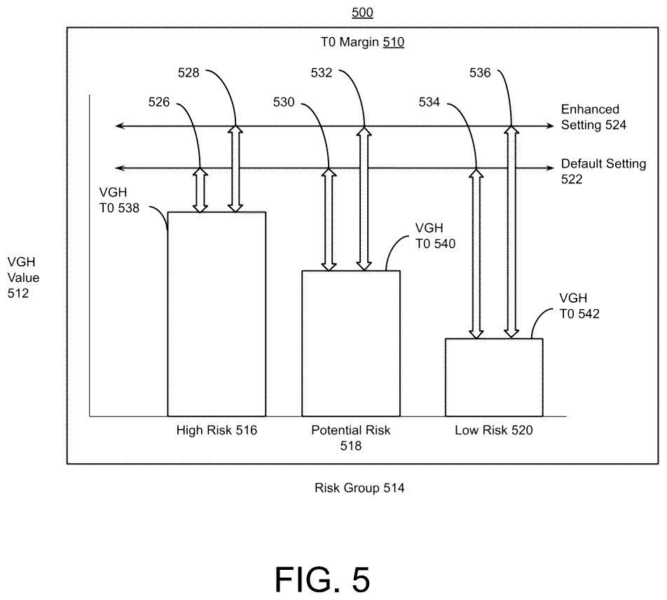

At block 312, a change in electronic low voltage supply source (ELVSS) voltage in response to a change in VGH may be measured. For example, such measurement may use a power management integrated circuit (PMIC) to track how ELVSS changes as VGH changes. It may be possible to detect VGH T0 because at VGH T0, the current changes from a relatively steady value to having a sharp increase. An example of such a change is provided at FIG. 5. Block 312 may be followed by block 318.

At block 314, an abnormality voltage threshold may be detected using a dedicated detection component. For example, such a dedicated detection component may recognize green artifacts or other incorrect behavior directly. For example, because there may an expectation to have the display show a black screen when it is being tested, if the display shows something that is greenish or bluish or something else that is not black, the display screen voltage or data current may not be the same as the initial setting. Accordingly, such display behavior may indicate an abnormality that suggests an increase to VGH is warranted. Block 314 may be followed by block 318.

At block 316, a change in supplied current may be detected using a system-on-a-chip (SoC). Such detection is similar to detection using a PMIC, but the SoC is a different component for such detection. The overall detection concept may be the same. However, because the SoC or the PMIC is prepared to include an additional pin to gather the information for the detection, it varies by product which technique is used based on where space for the detection pin is allocated. Block 316 may be followed by block 318.

At block 318, a risk level may be determined based on the change in ELVSS voltage, the results of the detection component, or the change in supplied current found using the SoC. Any of these techniques (and others) can tell that the display is not as set or expected. Accordingly, if this behavior occurs, it indicates that the display is at risk and a corresponding VGH voltage is to be applied. For example, the previous block may provide a VGH T0, which may indicate risk level based on which range of voltages the VGH T0 falls into.

In some implementations, various values of ELVSS current correspond to VGH values. For example, during successful operation, such as for a VGH value in a certain range, the ELVSS current values remain almost constant (the ELVSS current values are no greater than a set number of uA from one another). However, at a certain VGH, a set change in VGH causes a significant current increase that exceeds a threshold current change, which signals that the VGH T0 is reached.

Reducing VGH below VGH results in abnormal display behavior. Once VGH T0 is reached, small artifacts begin to appear on the display, which get worse and worse as VGH continues to decrease.

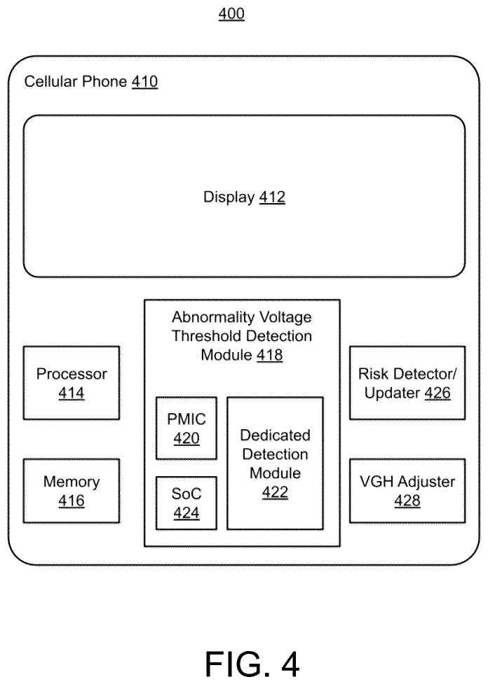

FIG. 4—Diagram of Cellular Phone with Display Having Reconfigurable VGH

FIG. 4 is a block diagram 400 illustrating a cellular phone with a display having a reconfigurable high level gate voltage (VGH), in accordance with some implementations. The cellular phone 410 may include a display 412, as well as a processor 414 and a memory 416. For example, the display 412 may be a thin-film transistor (TFT) display 412. The processor 414 and the memory 416 implement functions that drive display 412. The processor 414 and the memory 416 also manage the operation of abnormality voltage threshold detection module 418 (and its constituent elements PMIC 420, dedicated detection module 422, and SoC 424), risk detector/updater 426, and VGH adjuster 428).

The cellular phone 410 may also include an abnormality voltage threshold detection module 418. For example, the abnormality voltage threshold detection module 418 may include one or more of a power management integrated circuit (PMIC) 420, a dedicated detection module 422, and a system-on-a-chip (SoC) 424. However, these are only examples of components that may allow the abnormality voltage threshold detection module 418 to find VGH T0, and other implementations may detect VGH T0 in other ways or combine information from these components to ascertain the value of VGH T0.

The cellular phone 410 may also include a risk detector/updater 426 and a VGH adjuster 428. The risk detector/updater 426 takes the VGH T0 value produced by abnormality voltage threshold detection module 418 and determines a range corresponding to a risk value for that VGH T0 value. For example, there may be a range indicating low risk, a range indicating potential risk, and a range indicating high risk. The VGH T0 may change as the display 412 operates.

For example, if the display 412 is subject to electrostatic discharge (ESD), the VGH T0 may change and a low risk display 412 may move into the potential risk or high risk categories. By contrast, if the operating range of display 412 becomes more stable, the VGH T0 may also change and a potential risk display 412 or a high risk display 412 may fall into the low risk category. The risk detector/updater 426 may also update a risk level as the VGH T0 value is measured again.

The cellular phone 410 may also include a VGH adjuster 428. The VGH adjuster 428 changes the operating VGH of the display 412, when the risk level of the display 412 changes. When the operating VGH changes, there may be a greater operating margin, avoiding artifacts. However, the higher the VGH, the higher the power consumption, so it is best to keep the VGH as low as possible while avoiding display artifacts.

For example, a display 412 may originally fall into a low risk group, a potential risk group, or a high risk group based on its VGH T0 value, and be shipped with a default setting or enhanced setting accordingly. If the VGH T0 value changes, the setting may change accordingly as well.

FIG. 5—Margins for Displays with Various Risk Characteristics

FIG. 5 illustrates groupings of displays with various risk characteristics, in accordance with some implementations. FIG. 5 illustrates a graph of T0 margin characteristics 510. The graph has VGH values 512 as its vertical axis and horizontally illustrates risk group 514, with three example groupings of displays. The VGH values 512 show the relative values of VGH T0 for the groups and how they compare to the voltages for the default setting and the enhanced setting. The three groups include high risk displays 516 (a display has a VGH T0 is greater than a threshold), potential risk displays 518 (a display has a VGH T0 is in a moderate range such that artifacts are still a concern), and low risk displays 520 (a display that has VGH T0 in a low range and artifacts are therefore unlikely).

The displays may be set for default settings 522 (e.g., a set lower voltage) or enhanced settings (e.g., a set higher voltage). The high risk displays 516 are associated with a very small minimum margin 526 in the default settings 522 and with a larger margin 528 in the enhanced settings 524. These margins (delta values) refer to a difference between the VGH T0 of a given group and a driving VGH for which the display is set. By leaving this greater margin, high risk displays 516 are less likely to have display issues in the enhanced settings 524.

The potential risk displays 518 are associated with a relatively small minimum margin 530 in the default settings 522 and with a larger margin 532 in the enhanced settings 524. Hence, potential risk displays 518 are also set at the enhanced settings 524 to avoid display issues. The low risk displays 520 are associated with a significant minimum margin 534 in the default settings 522 and with a margin 536 that is even larger in the enhanced settings 524. However, it is possible to operate the low risk displays 520 at the default settings 522 safely because there is still a significant operating margin.

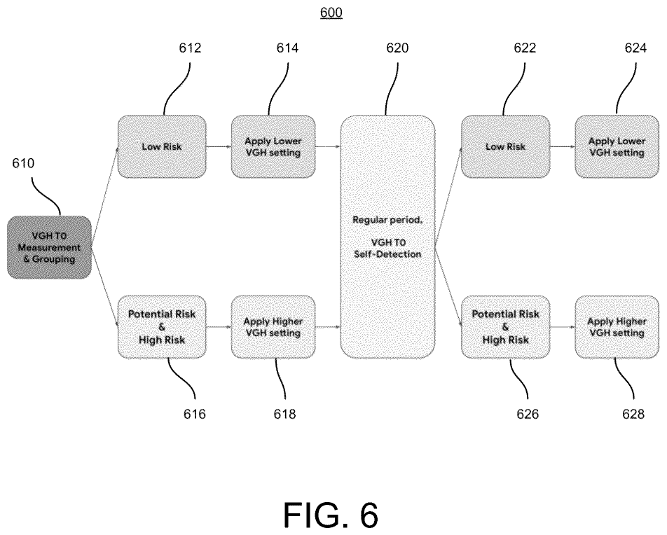

### FIG. 6—Example Process Flow

FIG. 6 illustrates an example of a process flow 600, in accordance with some implementations. For example, the process flow begins at block 610. At block 610, VGH T0 measurement and grouping is performed. For example, various techniques establish the VGH T0 value for each display. These VGH T0 values are grouped into low risk displays at block 612 and potential risk/high risk displays at block 616.

Accordingly, if a given display is considered a low risk display at block 612, block 612 may be followed by block 614. At block 614, a lower VGH setting is applied to that display. If a given display is considered a potential risk/high risk display at block 616, block 616 may be followed by block 618. At block 618, a higher VGH setting is applied to that display. Block 614 and block 618 may be followed by block 620.

At block 620, after regular periods (e.g., every day, week, month, etc.) or in response to other specific triggering events (e.g., a received command to measure the risk, a detected display abnormality, etc.), the device performs a VGH T0 self-detection (such as detailed in FIG. 3). Based on the results, block 620 may be followed by block 622 or block 626. Specifically, if the display is determined as a low risk display, block 620 is followed by block 622. If the display is determined as a potential risk or high risk display (a risk other than low risk), block 620 is followed by block 626.

Block 622 indicates a determination that a display is low risk. Accordingly, block 622 may be followed by block 624. At block 624 a lower (default) VGH setting is applied. In some implementations, the lower setting is only applied if this lower setting represents a change. In some implementations, the lower setting is re-applied when a lower setting is appropriate. In some implementations, the lower setting is a set value. In some implementations, the lower setting falls into a range, or may be based on a risk score.

Block 626 indicates a determination that a display is potential or high risk (i.e., not a low risk). Accordingly, block 626 may be followed by block 628. At block 628, a higher (enhanced) VGH setting is applied. This avoids screen issues, at the cost of higher power consumption. In some implementations, the higher setting is only applied if this higher setting represents a change. In some implementations, the higher setting is re-applied when a higher setting is appropriate. In some implementations, the higher setting is a set value. In some implementations, the higher setting falls into a range, or may be based on a risk score.

Because block 620 occurs at regular intervals, after block 622 and block 624 or block 626 and block 628 occur, there may still be remaining checks to see if adjustments to the risk occur that lead to a change of VGH setting.

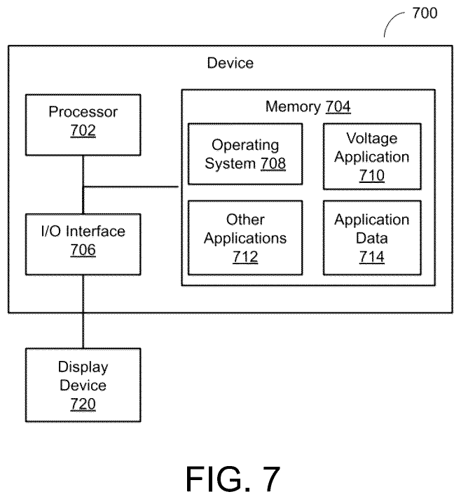

### FIG. 7—Example Computing Device

FIG. 7 is a block diagram of an example device 700 which may be used to implement one or more features described herein. In some implementations, device 700 may be used to implement a client device, a server device, or both client and server devices. Device 700 can be any suitable computer system, server, or other electronic or hardware device as described above.

One or more methods described herein can operate in several environments and platforms, e.g., as a standalone computer program that can be executed on any type of computing device, as a web application having web pages, a program run on a web browser, a mobile application (“app”) run on a mobile computing device (e.g., cell phone, smart phone, tablet computer, wearable device (wristwatch, armband, jewelry, headwear, virtual reality goggles or glasses, augmented reality goggles or glasses, head mounted display, etc.), laptop computer, etc.). In one example, a client/server architecture can be used, e.g., a mobile computing device (as a client device) sends user input data to a server device and receives from the server the final output data for output (e.g., for display). In another example, all computations can be performed within the mobile app (and/or other apps) on the mobile computing device. In another example, computations can be split between the mobile computing device and one or more server devices.

In some implementations, device 700 includes a processor 702, a memory 704, and input/output (I/O) interface 706. Processor 702 can be one or more processors and/or processing circuits to execute program code and control basic operations of the device 700. A “processor” includes any suitable hardware system, mechanism or component that processes data, signals or other information. A processor may include a system with a general-purpose central processing unit (CPU) with one or more cores (e.g., in a single-core, dual-core, or multi-core configuration), multiple processing units (e.g., in a multiprocessor configuration), a graphics processing unit (GPU), a field-programmable gate array (FPGA), an application-specific integrated circuit (ASIC), a complex programmable logic device (CPLD), dedicated circuitry for achieving functionality (e.g., one or more hardware image decoders and/or video decoders), a special-purpose processor to implement neural network model-based processing, neural circuits, processors optimized for matrix computations (e.g., matrix multiplication), or other systems. In some implementations, processor 702 may include one or more co-processors that implement neural-network processing. In some implementations, processor 702 may be a processor that processes data to produce probabilistic output, e.g., the output produced by processor 702 may be imprecise or may be accurate within a range from an expected output. Processing need not be limited to a particular geographic location, or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory.

Memory 704 is typically provided in device 700 for access by the processor 702, and may be any suitable processor-readable storage medium, such as random access memory (RAM), read-only memory (ROM), Electrical Erasable Read-only Memory (EEPROM), Flash memory, etc., suitable for storing instructions for execution by the processor, and located separate from processor 702 and/or integrated therewith. Memory 704 can store software operating on the server device 700 by the processor 702, including an operating system 708, voltage application 710 (e.g., which may be abnormality voltage threshold detection module 418, risk detector/updater 426, and/or VGH adjuster 428 of FIG. 4), other applications 712, and application data 714. Other applications 712 may include applications such as a data display engine, web hosting engine, map applications, video display engine, notification engine, social networking engine, media display applications, communication applications, web hosting engines or applications, media sharing applications, etc. In some implementations, the voltage application 710 can include instructions that enable processor 702 to perform functions described herein, e.g., some or all of the methods of FIGS. 1-3. In some implementations, images and videos stored in the formats described herein (including recovery maps, recovery map tracks, metadata, metadata tracks, etc.) can be stored as application data 714 or other data in memory 704, and/or on other storage devices of one or more other devices in communication with device 700. In some examples, voltage application 710, or other applications stored in memory 704, can include abnormality voltage threshold detection 160, risk detector/updater 170, and/or VGH adjuster 172 module(s) (e.g., performing methods of FIGS. 1-3), or such modules can be integrated into fewer or a single module or application.

Any software in memory 704 can alternatively be stored on any other suitable storage location or computer-readable medium. In addition, memory 704 (and/or other connected storage device(s)) can store one or more messages, one or more taxonomies, electronic encyclopedia, dictionaries, digital maps, thesauruses, knowledge bases, message data, grammars, user preferences, and/or other instructions and data used in the features described herein. Memory 804 and any other type of storage (magnetic disk, optical disk, magnetic tape, or other tangible media) can be considered “storage” or “storage devices.”

I/O interface 706 can provide functions to enable interfacing the server device 700 with other systems and devices. Interfaced devices can be included as part of the device 700 or can be separate and communicate with the device 700. For example, network communication devices, storage devices (e.g., memory and/or database), and input/output devices can communicate via I/O interface 706. In some implementations, the I/O interface can connect to interface devices such as input devices (keyboard, pointing device, touchscreen, microphone, camera, scanner, sensors, etc.) and/or output devices (display devices, speaker devices, printers, motors, etc.).

Some examples of interfaced devices that can connect to I/O interface 706 can include one or more display devices 720 that can be used to display content, e.g., images, video, and/or a user interface of an application as described herein. Display device 720 can be connected to device 700 via local connections (e.g., display bus) and/or via networked connections and can be any suitable display device. Display device 720 can include any suitable display device such as an LCD, LED, or plasma display screen, CRT, television, monitor, touchscreen, 3-D display screen, or other visual display device. Display device 720 may also act as an input device, e.g., a touchscreen input device. For example, display device 720 can be a flat display screen provided on a mobile device, multiple display screens provided in glasses or a headset device, or a monitor screen for a computer device.

The I/O interface 706 can interface to other input and output devices. Some examples include one or more cameras which can capture images and videos and/or detect gestures. Some implementations can provide a microphone for capturing sound (e.g., as a part of captured videos, voice commands, etc.), a radar or other sensors for detecting gestures, audio speaker devices for outputting sound, or other input and output devices.

For ease of illustration, FIG. 7 shows one block for each of processor 702, memory 704, I/O interface 706, and software blocks 708-714. These blocks may represent one or more processors or processing circuitries, operating systems, memories, I/O interfaces, applications, and/or software modules. In other implementations, device 700 may not have all of the components shown and/or may have other elements including other types of elements instead of, or in addition to, those shown herein. While some components are described as performing blocks and operations as described in some implementations herein, any suitable component or combination of components of cellular phone 410, device 700, similar systems, or any suitable processor or processors associated with such a system, may perform the blocks and operations described.

Methods described herein can be implemented by computer program instructions or code, which can be executed on a computer. For example, the code can be implemented by one or more digital processors (e.g., microprocessors or other processing circuitry) and can be stored on a computer program product including a non-transitory computer-readable medium (e.g., storage medium), such as a magnetic, optical, electromagnetic, or semiconductor storage medium, including semiconductor or solid state memory, magnetic tape, a removable computer diskette, a random access memory (RAM), a read-only memory (ROM), flash memory, a rigid magnetic disk, an optical disk, a solid-state memory drive, etc. The program instructions can also be contained in, and provided as, an electronic signal, for example in the form of software as a service (SaaS) delivered from a server (e.g., a distributed system and/or a cloud computing system). Alternatively, one or more methods can be implemented in hardware (logic gates, etc.), or in a combination of hardware and software. Example hardware can be programmable processors (e.g. Field-Programmable Gate Array (FPGA), Complex Programmable Logic Device), general purpose processors, graphics processors, Application Specific Integrated Circuits (ASICs), and the like. One or more methods can be performed as part of or component of an application running on the system, or as an application or software running in conjunction with other applications and operating systems.

Although the description has been described with respect to particular implementations thereof, these particular implementations are merely illustrative, and not restrictive. Concepts illustrated in the examples may be applied to other examples and implementations.

Further to the descriptions above, a user may be provided with controls allowing the user to make an election as to both if and when systems, programs, or features described herein may enable collection of user information (e.g., information about a user's social network, social actions, or activities, profession, a user's preferences, or a user's current location), and if the user is sent content or communications from a server. In addition, certain data may be treated in one or more ways before it is stored or used, so that personally identifiable information is removed. For example, a user's identity may be treated so that no personally identifiable information can be determined for the user, or a user's geographic location may be generalized where location information is obtained (such as to a city, ZIP code, or state level), so that a particular location of a user cannot be determined. Thus, the user may have control over what information is collected about the user, how that information is used, and what information is provided to the user.

Note that the functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, operations, or computations may be presented in a specific order, the order may be changed in different particular implementations. In some implementations, multiple steps or operations shown as sequential in this specification may be performed at the same time.

Although the description has been described with respect to particular implementations thereof, these particular implementations are merely illustrative, and not restrictive. Concepts illustrated in the examples may be applied to other examples and implementations.

The functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, operations, or computations may be presented in a specific order, the order may be changed in different particular implementations. In some implementations, multiple steps or operations shown as sequential in this specification may be performed at the same time.

In the above detailed description, reference is made to the accompanying drawings, which form a part hereof. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented herein. Aspects of the present disclosure, as generally described herein, and illustrated in the figures, can be arranged, substituted, combined, separated, and designed in a wide variety of different configurations, all of which are contemplated herein.

References in the specification to “some implementations,” “an implementation,” “an example implementation,” etc. indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, such feature, structure, or characteristic may be effected in connection with other implementations whether or not explicitly described.

We claim:

1. A computing device comprising a processor coupled to a display, wherein a high level gate voltage (VGH) of the display is configured by:
measuring an abnormality voltage threshold for the display;
determining a risk level for the display based on the abnormality voltage threshold; and
setting the VGH of the display based on the risk level.

2. The computing device of claim 1, wherein setting the VGH comprises setting the VGH to a predetermined low value when the risk level is a low risk level and setting the VGH to a predetermined high value when the risk level is not the low risk level.

3. The computing device of claim 1, wherein setting the VGH of the display is performed in a factory before the computing device is shipped.

4. The computing device of claim 1, wherein the VGH is adjusted after the display has been in use, by:
determining whether the risk level for the display has changed; and
in response to determining that the risk level for the display has changed, adjusting the VGH of the display.

5. The computing device of claim 4, wherein determining that the risk level for the display has changed comprises:
determining if the abnormality voltage threshold for the display has increased based on one or more of:
measuring, using a power management integrated circuit (PMIC) of the computing device, an increase exceeding a threshold increase in supplied current supplied by an electronic low voltage supply source (ELVSS) to the display in response to a predetermined decrease in VGH;
detecting the abnormality voltage threshold using an abnormality voltage detection component of the device, wherein the abnormality voltage detection component detects abnormal behavior by the display; and
detecting the abnormality voltage threshold based on detecting an increase exceeding a threshold increase in supplied current measured using a System-on-a-Chip (SoC) of the computing device in response to a predetermined decrease in VGH, and
wherein adjusting the VGH of the display comprises increasing the VGH.

6. The computing device of claim 4, wherein determining that the risk level for the display has changed comprises determining if the abnormality voltage threshold for the display has decreased, and wherein adjusting the VGH of the display comprises decreasing the VGH.

7. The computing device of claim 4, wherein determining whether the measuring the abnormality voltage threshold and the determining the risk level for the display has changed are performed at multiple occasions during a lifetime of the computing device and the setting the VGH is performed based on the measuring and the determining.

8. The computing device of claim 1, wherein the display includes a thin-film transistor (TFT) panel.

9. A computer-implemented method to control a high level gate voltage (VGH) of a display, comprising:
measuring an abnormality voltage threshold for the display;
determining a risk level for the display based on the abnormality voltage threshold; and
setting the VGH of the display based on the risk level.

10. The computer-implemented method of claim 9, wherein setting the VGH comprises setting the VGH to a predetermined low value when the risk level is a low risk level and setting the VGH to a predetermined high value when the risk level is not the low risk level.

11. The computer-implemented method of claim 9, wherein setting the VGH of the display is performed in a factory before the computing device is shipped.

12. The computer-implemented method of claim 9, wherein the VGH is adjusted after the display has been in use, by:
determining whether the risk level for the display has changed; and
in response to determining that the risk level for the display has changed, adjusting the VGH of the display.

13. The computer-implemented method of claim 12, wherein determining that the risk level for the display has changed comprises:
determining if the abnormality voltage threshold for the display has increased based on one or more of:
measuring, using a power management integrated circuit (PMIC) of the computing device, an increase exceeding a threshold increase in supplied current supplied by an electronic low voltage supply source (ELVSS) to the display in response to a predetermined decrease in VGH;
detecting the abnormality voltage threshold using an abnormality voltage detection component of the device, wherein the abnormality voltage detection component detects abnormal behavior by the display; and
detecting the abnormality voltage threshold based on detecting an increase exceeding a threshold increase in supplied current measured using a System-on-a-Chip (SoC) of the computing device in response to a predetermined decrease in VGH, and
wherein adjusting the VGH of the display comprises increasing the VGH.

14. The computer-implemented method of claim 12, wherein determining that the risk level for the display has changed comprises determining if the abnormality voltage threshold for the display has decreased, and wherein adjusting the VGH of the display comprises decreasing the VGH.

15. The computer-implemented method of claim 12, wherein determining whether the measuring the abnormality voltage threshold and the determining the risk level for the display has changed are performed at multiple occasions during a lifetime of the computing device and the setting the VGH is performed based on the measuring and the determining.

16. The computer-implemented method of claim 9, wherein the display includes a thin-film transistor (TFT) panel.

17. A cellular phone comprising:
a computing device comprising a processor coupled to a display, wherein a high level gate voltage (VGH) of the display is configured by:
measuring an abnormality voltage threshold for the display;
determining a risk level for the display based on the abnormality voltage threshold; and
setting the VGH of the display based on the risk level.

18. The cellular phone of claim 17, wherein setting the VGH of the display is performed in a factory before the cellular phone is shipped.

19. The cellular phone of claim 17, wherein the VGH is adjusted after the display has been in use, by:
determining whether the risk level for the display has changed; and
in response to determining that the risk level has changed, adjusting the VGH of the display.

20. The cellular phone of claim 19, wherein determining that the risk level for the display has changed comprises:
determining if the abnormality voltage threshold for the display has increased based on one or more of:
measuring, using a power management integrated circuit (PMIC) of the computing device, an increase exceeding a threshold increase in supplied current supplied by an electronic low voltage supply source (ELVSS) to the display in response to a predetermined decrease in VGH;
detecting the abnormality voltage threshold using an abnormality voltage detection component of the device, wherein the abnormality voltage detection component detects abnormal behavior by the display; and
detecting the abnormality voltage threshold based on detecting an increase exceeding a threshold increase in supplied current measured using a System-on-a-Chip (SoC) of the computing device in response to a predetermined decrease in VGH, and
wherein adjusting the VGH of the display comprises increasing the VGH.
